(19) United States
(12) Patent Application Publication
(10) Pub. No.: US 2026/0141971 A1
(43) Pub. Date: May 21, 2026

(54) TEST MODE MONITORING AND FEEDBACK

(71) Applicant: Micron Technology, Inc., Boise, ID (US)

(72) Inventors: Aaron P. BOEHM, Boise, ID (US); Scott E. SCHAEFER, Boise, ID (US); Toru ISHIKAWA, Kanagawa (JP)

(21) Appl. No.: 19/259,964

(22) Filed: Jul. 3, 2025

Related U.S. Application Data
(60) Provisional application No. 63/722,296, filed on Nov. 19, 2024.

(51) Int. Cl. G11C 29/44

(52) U.S. Cl. CPC G11C 29/44

(57) ABSTRACT

Implementations described herein relate to test mode monitoring and feedback. In some implementations, a memory apparatus may detect, by a test mode monitor component of the memory apparatus, that the memory apparatus has entered a test mode based on one or more test mode signals. The memory apparatus may provide, to a host system, a message indicating that the memory apparatus has entered the test mode.

### CROSS-REFERENCE TO RELATED APPLICATION

This Patent Application claims priority to U.S. Provisional Patent Application No. 63/722,296, filed on Nov. 19, 2024, entitled “TEST MODE MONITORING AND FEEDBACK,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to test mode monitoring and feedback.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of test mode monitoring and feedback.

FIG. 2 is a diagram of an example system that supports test mode monitoring and feedback.

FIG. 3 is a diagram of an example that supports test mode monitoring and feedback.

FIG. 4 is a flowchart of an example method associated with test mode monitoring and feedback.

### DETAILED DESCRIPTION

Some memory systems may support a test mode that enables altered functionality of a memory system. For example, a memory system may include various test mode circuits to facilitate testing and evaluation during the manufacturing process. These test mode circuits may adjust memory system parameters, such as voltage levels for access operations (e.g., trim parameters) and/or timing information, among other examples, through test mode inputs. However, a memory system entering a test mode may compromise the reliability and/or safety of the memory system. For example, a soft error rate (SER) event and/or other faults, such as a shorted line, may inadvertently cause the memory system to enter a test mode, which may compromise the reliability of the memory system by leading to data corruption, addressing faults, and critical errors.

Further, an unauthorized third party may attempt to enable a test mode to bypass security features of the memory system to initiate a denial of service, corrupt sensitive data, and/or or gain unauthorized access to system functionalities. For example, unauthorized access to a memory system through test mode may allow a third party to exploit the altered functionalities to read or modify sensitive information. This unauthorized access may result in data breaches in which confidential or personal information may be exposed.

Some implementations described herein enable test mode monitoring and feedback. For example, the memory system may detect that the memory system has entered a test mode. The memory system may include a test mode monitor component configured to monitor one or more test mode signals. For example, the test mode monitor component may evaluate the logic states of the one or more test mode signals to determine whether at least one of the one or more test mode signals has transitioned from a first logic state (e.g., an inactive state) to a second logic state (e.g., an active state). If the test mode monitor component determines that at least one of the test mode signals is active, then the memory system may determine that the memory system has entered a test mode. In some examples, the memory system may store a value indicating that the memory system has entered the test mode to a mode register.

In some examples, a host system may provide, and the memory system may obtain, a read command for the mode register. Based on, in response to, or otherwise associated with obtaining the read command, the memory system may provide, and the host system may obtain, a message that includes the value of the mode register. Additionally, or alternatively, the memory system may provide the message without obtaining an explicit request from the host system. For example, the memory system may provide the alert flag to the host system via an alert pin.

As a result, enabling test mode monitoring and feedback may improve the security and reliability of the memory system. For example, by detecting and alerting unauthorized or inadvertent entry into test modes, the memory system may safeguard against potential data corruption, such as addressing faults or other errors. Such protection may further reduce the quantity of failures per unit of time of operating the memory system (e.g., may reduce the failures in time (FIT) rate). Further, by alerting the host system via an alert pin and/or mode register, the memory system may enable swift host system responses, which may improve the ability of the host system to perform precautionary operations.

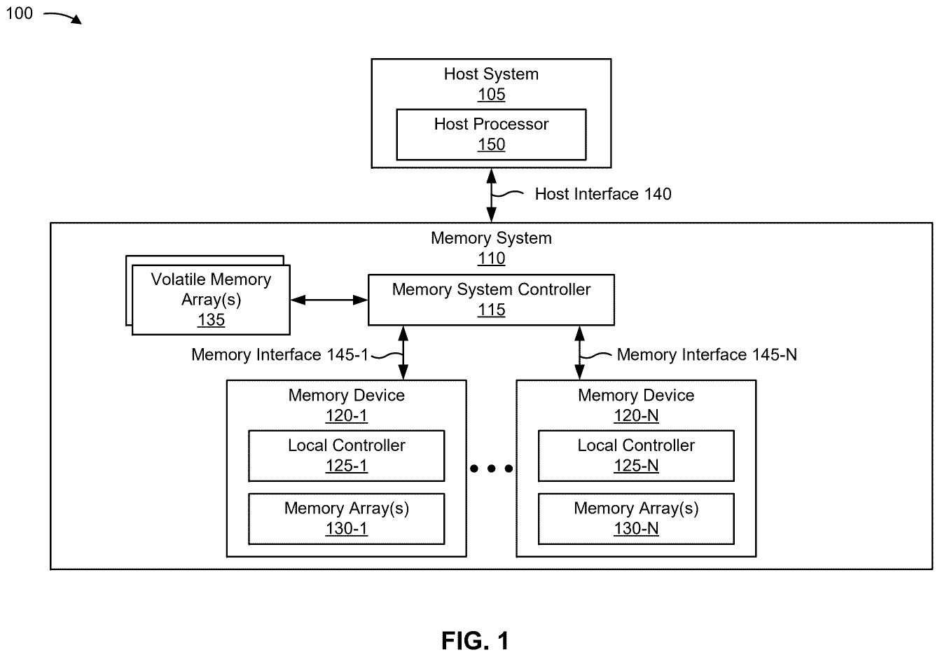

FIG. 1 is a diagram illustrating an example system 100 capable of test mode monitoring and feedback. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to detect that a memory device has entered a test mode based on one or more test mode signals; and provide, to a host system, a message indicating that the memory device has entered the test mode.

In some implementations, one or more systems, devices, apparatuses, components, and/or controllers of FIG. 1 may be configured to detect that a memory device has entered a test mode based on one or more test mode signals; and transmit, to a host system and via an alert pin, a flag indicating that the memory device has entered the test mode.

In some implementations, one or more systems, devices, apparatuses, components, and/or controllers of FIG. 1 may be configured to detect that a memory device has entered a test mode based on one or more test mode signals; and store, to a mode register of the memory device, a value indicating that the memory device has entered the test mode.

In some implementations, one or more systems, devices, apparatuses, components, and/or controllers of FIG. 1 may be configured to a detect that a memory system has entered a test mode based on one or more test mode signals; and communicate, to a host system via a host interface, a message indicating that the memory system has entered the test mode.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

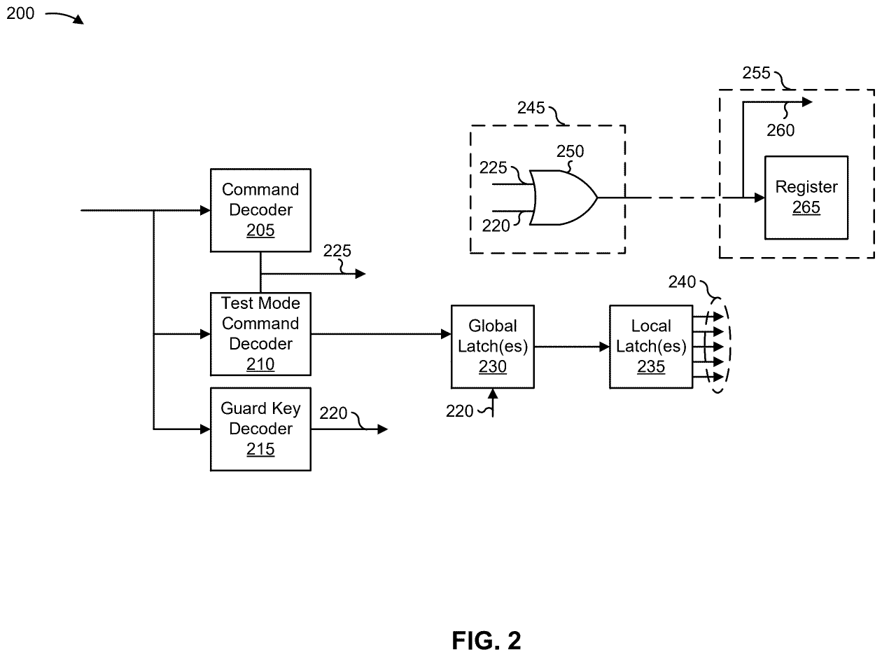

FIG. 2 is a diagram of an example system 200 that supports test mode monitoring and feedback. The system 200 may include aspects of and/or may be implemented by a memory apparatus, such as the memory system 110 and/or a memory device 120. For example, the system 200 may be implemented in the memory system controller 115, in a local controller 125, and/or elsewhere within the memory apparatus. The memory apparatus may use the system 200 as part of determining whether the memory apparatus has entered a test mode (e.g., as part of a testing procedure and/or due to inadvertent or malicious causes).

A test mode may be a state of the memory apparatus in which the memory system performs testing operations, such as diagnostic, debugging, and/or configuration operations. In some cases, the memory system may enter the test mode based on decoding one or more commands from the host system using the command decoder 205, the test mode command decoder 210, and/or the guard key decoder 215. These decoders may obtain one or more commands (e.g., from a host system) and, if they match the specified criteria, may initiate a test mode within the memory apparatus. Additionally, or alternatively, a fault may cause the memory apparatus to enter a test mode. For example, a soft error event or physical damage, such as a shorted line, may cause the memory apparatus to enter a test mode.

For example, to initiate a test mode, the host system may provide, and the memory system may obtain, a guard key command sequence. A guard key command sequence may be a set of commands that, when received in a specific order or arrangement, indicates that the memory apparatus is to initiate the test mode. The memory apparatus may route the guard key command sequence to the guard key decoder 215. Based on, in response to, or otherwise associated with obtaining the guard key sequence, the guard key decoder 215 may validate the guard key sequence (e.g., may determine whether the guard kay command sequence matches the specific order or arrangement). If the guard key command sequence is valid, then the guard key decoder 215 may output one or more test mode signals 220 to one or more components of the system 200.

To execute test mode commands, the host system may provide, and the memory system may obtain, one or more test mode commands. A test mode command may be a command indicating that the memory apparatus is to execute one or more test mode functions and/or access test mode circuitry segments. The test mode command decoder 210 may decode the one or more test mode commands and may output one or more test mode signals 225.

The test mode signal(s) 220 and/or the test mode signal(s) 225 may cause the memory apparatus to perform one or more test mode operations. For example, the guard key decoder 215 and the test mode command decoder 210 may respectively provide the test mode signal(s) 220 and the test mode signal(s) 225 to one or more global latches 230 and/or one or more local latches 235. The one or more global latches 230 and the one or more local latches 235 may store operational parameters of the memory apparatus, such as voltage levels and timing information. Based on, in response to, or otherwise associated with obtaining the test mode signal(s) 220 and/or the test mode signal(s) 225, the global latch(es) 230 may set or adjust various parameters, such as global voltage references and/or clock timing parameters. For example, the global latch(es) 230 may adjust voltage trim levels across the memory apparatus.

Further, the local latch(es) 235 may support granular control of specific areas or circuits within the memory apparatus. For example, a local latch 235 may store configuration parameters associated with a subsection of the memory apparatus, such as individual banks or rows of memory cells. In some examples, the local latch(es) 235 may output one or more local test mode signals 240. The local test mode signal(s) 240 may indicate whether respective components of the memory apparatus have entered a test mode. A local test mode signal 240 may provide real-time feedback or status updates specific to the component under test. For example, as part of a diagnostic routine, a local latch 235 may output a local test mode signal 240 indicating whether a particular memory cell is functioning correctly or if it has experienced a fault condition.

The system 200 may include a test mode monitoring component 245. The test mode monitoring component 245 may be configured to obtain one or more test signals, such as the test mode signal(s) 220, 225, and/or the local test mode signal(s) 240. The test mode monitoring component 245 may output a value based on the one or more test mode signals. For example, the test mode monitoring component 245 may include circuitry, such as one or more logic gates 250 (e.g., one or more OR gates), configured to determine whether at least one of the one or more test mode signals has transitioned from a first logic state to a second logic state. For example, the test mode monitoring component 245 may identify whether a particular test mode signal of the one or more test mode signals switches from an inactive (e.g., low) state to an active (e.g., high) state. Said another way, the test mode monitoring component 245 may selectively output an indication that the memory apparatus has entered a test mode based on the one or more test mode signals. As used herein, “selectively” performing an operation means to either perform the operation or refrain from performing the operation. For example, selectively performing an operation based on whether a condition is satisfied means that the operation is performed if the condition is satisfied and that the operation is not performed if the condition is not satisfied (or vice versa). Thus, selectively performing an operation may include determining whether to perform the operation and then either performing the operation or refraining from performing the operation based on that determination. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

For example, if at least one of the one or more test mode signals is active (e.g., in a high state), then the test mode monitoring component 245 may output a first value, such as an active signal, indicating that the memory apparatus has entered the test mode. Alternatively, if none of the one or more test mode signals is active (e.g., if each of the one or more test mode signals is inactive), then the test mode monitoring component 245 may output a second value, such as an inactive signal, indicating that the memory apparatus has not entered the test mode.

The system 200 may include a test mode alert component 255 configured to provide, to the host system, a message indicating whether the memory apparatus has entered a test mode. The test mode alert component 255 may obtain, as an input, a value (e.g., the output of the test mode monitoring component 245) indicating whether the memory apparatus has entered a test mode. In some implementations, to provide the message to the host system, the test mode alert component 255 may transmit the message as an alert flag via an alert pin 260 to the host system. The alert flag may be a binary value, such as a first logic state (e.g., a logic “1”, a high state) indicating that the memory apparatus has entered the test mode, or a second logic state (e.g., a logic “0”, a low state) indicating that the memory apparatus has not entered the test mode. The alert pin 260 may be a dedicated pin (e.g., channel, line) that, if driven to an active (e.g., high) state, indicates to the host system that the memory apparatus has entered a test mode. By alerting the host system via the alert pin 260, the memory apparatus may swiftly communicate an initiation of the test mode to the host system. Such an alert may allow the host system to take one or more precautionary actions, such as transitioning to a safe mode, a lock-down mode, and/or taking steps to prevent potential data corruption or other test-mode-induced systemic failures.

Additionally, or alternatively, the test mode alert component 255 may store a value indicating that the memory system has entered the test mode, such as the alert flag, to a mode register 265. The mode register 265 may be a register configured to store various operational states or other parameters associated with the memory system. In some examples, the host system may poll (e.g., periodically and/or based on one or more conditions) the mode register 265. For example, the host system may provide, and the memory system may obtain, a read command indicating that the memory system is to provide the contents of the mode register 265 (e.g., the value of the alert flag) to the host system. Based on, in response to, or otherwise associated with obtaining the read command, the memory system may provide, and the host system may obtain, a message indicating the value of the alert flag.

In some examples, the system 200 may determine an initiation condition for a test mode. An initiation condition for a test mode may indicate a circumstance under which the memory apparatus is triggered to activate the test mode, such as the reception of a specific command sequence (e.g., one or more test mode commands and/or a guard key command sequence), a hardware fault, and/or other system-event-driven conditions. For example, if the memory system initiates the test mode in response to obtaining a guard key command sequence, then the initiation condition may include an indication that the test mode was initiated in response to obtaining the guard key command sequence. In such examples, the memory system may provide a message indicating the initiation condition to the host system. For example, the memory system may transmit a signal indicating the initiating condition to the host system (e.g., via the alert pin 260 or one or more separate pins). Additionally, or alternatively, the memory system may store a value indicating the initiation condition to one or more mode registers (e.g. the mode register 265 and/or one or more separate mode registers). By indicating the initiation condition of a test mode to the host system, the memory system may provide enhanced diagnostic information to the host system, which may improve the ability of the host system to take one or more precautionary actions.

As indicated above, FIG. 2 is provided as an example. Other examples may differ from what is described with regard to FIG. 2.

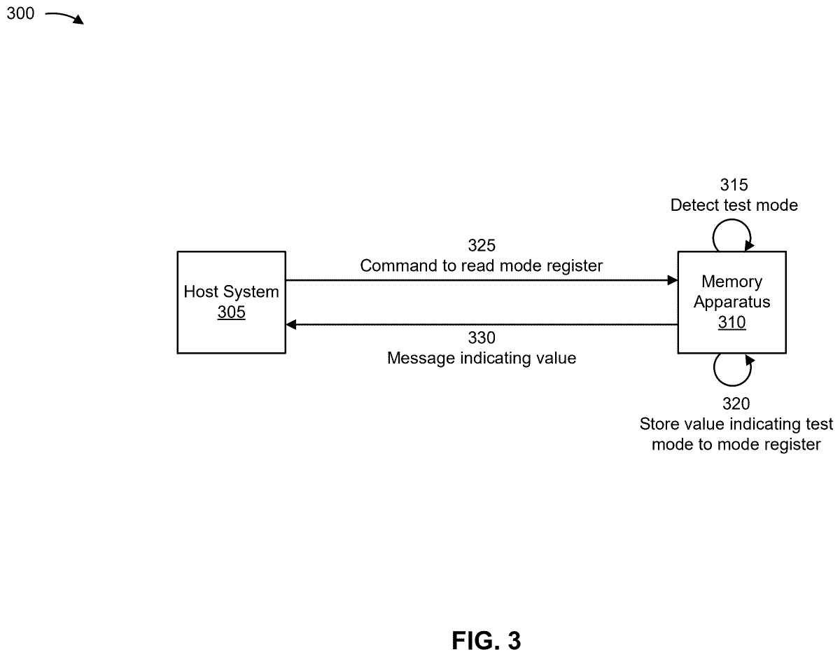

FIG. 3 is a diagram of an example 300 that supports test mode monitoring and feedback. The operations described in connection with FIG. 3 may be performed by the memory system 110 and/or one or more components of the memory system 110, such as the memory system controller 115, one or more memory devices 120, one or more local controllers 125, and/or the system 200. Additionally, or alternatively, the operations described in connection with FIG. 3 may be performed by the system 100, the host system 105, one or more components of the host system 105 (e.g., the host processor 150), and/or the host interface 140.

As shown in FIG. 3, the example 300 may include a host system 305 and a memory apparatus 310. The host system 305 may be the host system 105. The memory apparatus 310 may be, or may include, the memory system 110, one or more memory devices 120, one or more controllers (e.g., the memory system controller 115 and/or one or more local controllers 125), and/or the system 200.

As shown by reference number 315, the memory apparatus 310 may detect that the memory apparatus 310 has entered a test mode. The memory apparatus 310 may include a test mode monitor component (e.g., the test mode monitor component 245) configured to monitor the one or more test mode signals. For example, the test mode monitor component may evaluate the logic states of the one or more test mode signals to determine whether at least one of the one or more test mode signals has transitioned from a first logic state (e.g., an inactive state) to a second logic state (e.g., an active state). If the test mode monitor component determines that at least one of the test mode signals is active, then the memory apparatus 310 may determine that the memory apparatus 310 has entered a test mode. In some examples, as shown by reference number 320, the memory apparatus 310 may store, to a mode register, a value indicating that the memory apparatus 310 has entered the test mode. For example, the memory apparatus 310 may store an alert flag to the mode register. The alert flag may include a binary indication of test mode activation.

As shown by reference number 325, the host system 305 may (e.g., via the host interface 140) provide, and the memory apparatus 310 may obtain, a read command for the mode register. The host system 305 may poll the mode register periodically and/or in response to a trigger, such as an unexpected behavior observed in the memory apparatus 310 system that may be symptomatic of unwarranted test mode entry. As shown by reference number 330, based on, in response to, or otherwise associated with obtaining the read command, the memory apparatus 310 may provide, and the host system 305 may (e.g., via the host interface 140) obtain, a message that includes the value of the mode register. Additionally, or alternatively, the memory apparatus 310 may provide the message without obtaining an explicit request from the host system 305. For example, the memory apparatus 310 may provide the alert flag to the host system 305 via an alert pin.

By alerting the host system 305 of the test mode, the memory apparatus 310 may reduce the likelihood of data corruption due to inadvertent initiation of the test mode. Such protection may further reduce the quantity of failures per unit of time of operating the memory apparatus 310. Further, by alerting the host system 305 via the alert pin and/or mode register, the memory apparatus 310 may enable swift host system responses, which may improve the ability of the host system 305 to perform precautionary operations.

In some examples, the memory apparatus 310 may determine an initiation condition associated with the test mode. For example, if the memory apparatus 310 initiates the test mode in response to obtaining a guard key command sequence, then the initiation condition may include an indication that the test mode was initiated in response to obtaining the guard key command sequence. In such examples, the memory apparatus 310 may provide a message indicating the initiation condition to the host system 305. In some cases, the memory apparatus 310 may indicate the initiation condition in the same message as the alert flag. Alternatively, the memory apparatus 310 may indicate the initiation condition via a second message.

In some examples, based on, in response to, or otherwise associated with obtaining the message, the host system 305 may perform one or more precautionary actions. For example, the host system 305 may initiate a safe mode of the memory apparatus 310, may disable one or more functions of the memory apparatus 310, and/or may power down the memory apparatus 310, among other examples.

As indicated above, FIG. 3 is provided as an example. Other examples may differ from what is described with regard to FIG. 3.

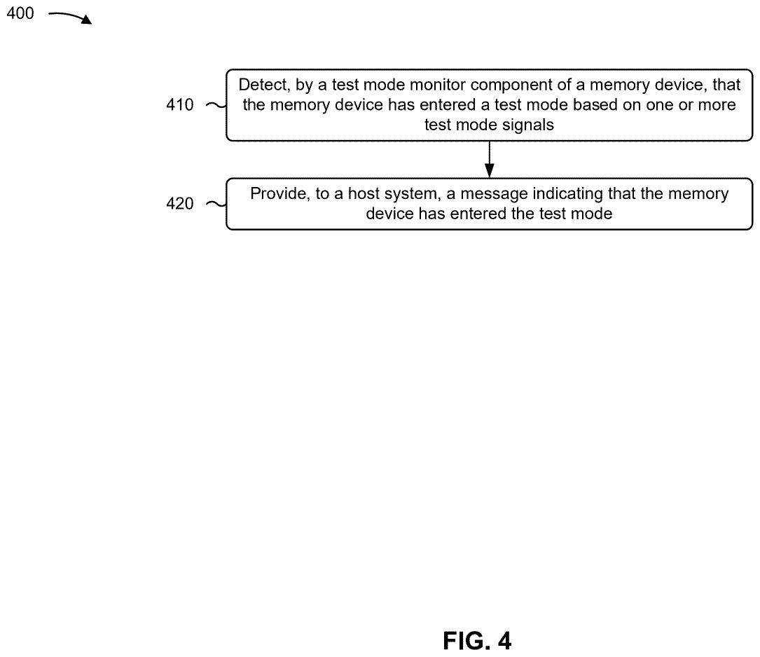

FIG. 4 is a flowchart of an example method 400 associated with test mode monitoring and feedback. In some implementations, a memory apparatus (e.g., the memory system 110, the memory device 120, and/or the system 200) may perform or may be configured to perform the method 400. In some implementations, another device or a group of devices separate from or including the memory apparatus (e.g., the host system 105 and/or the host interface 140) may perform or may be configured to perform the method 400. Additionally, or alternatively, one or more components of the memory apparatus (e.g., the memory system controller 115, one or more local controllers 125, one or more memory arrays 130, one or more volatile memory arrays 135, and/or one or more memory interfaces 145) may perform or may be configured to perform the method 400. Thus, means for performing the method 400 may include the memory device and/or one or more components of the memory device. Additionally, or alternatively, a non-transitory computer-readable medium may store one or more instructions that, when executed by the memory apparatus (e.g., the memory system controller 115 of the memory system 110 and/or the local controller 125 of the memory device 120), cause the memory device to perform the method 400.

As shown in FIG. 4, the method 400 may include detecting that the memory apparatus has entered a test mode based on one or more test mode signals (block 410). As further shown in FIG. 4, the method 400 may include providing, to a host system, a message indicating that the memory apparatus has entered the test mode (block 420).

The method 400 may include additional aspects, such as any single aspect or any combination of aspects described below and/or described in connection with one or more other methods or operations described elsewhere herein.

In a first aspect, the method 400 includes transmitting the alert flag to the host system via an alert pin.

In a second aspect, alone or in combination with the first aspect, the method 400 includes storing a value indicating that the memory apparatus has entered the test mode to a mode register of the memory apparatus.

In a third aspect, alone or in combination with one or more of the first and second aspects, the method 400 includes obtaining, from the host system, a read command for the mode register, and transmitting the value to the host system.

In a fourth aspect, alone or in combination with one or more of the first through third aspects, the method 400 includes obtaining, from the host system, a guard key command sequence, and initiating the test mode based on obtaining the guard key command sequence.

In a fifth aspect, alone or in combination with one or more of the first through fourth aspects, the method 400 includes determining an initiation condition associated with the test mode, and providing, to the host system, a second message indicating the initiation condition.

In a sixth aspect, alone or in combination with one or more of the first through fifth aspects, the method 400 includes determining that a test mode signal of the one or more test mode signals has transitioned from a first logic state to a second logic state.

In a seventh aspect, alone or in combination with one or more of the first through sixth aspects, the one or more test mode signals comprise a first test mode signal associated with a test mode command sequence and a second test mode signal associated with a guard key command sequence.

In an eighth aspect, alone or in combination with one or more of the first through seventh aspects, the one or more test mode signals comprise one or more local test mode signals indicating whether respective components of the memory apparatus have entered a test mode.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory device includes one or more components configured to: detect, by a test mode monitor component of the memory device, that the memory device has entered a test mode based on one or more test mode signals; and provide, to a host system, a message indicating that the memory device has entered the test mode.

In some implementations, a memory device includes one or more components configured to: detect, by a test mode monitor component of the memory device, that the memory device has entered a test mode based on one or more test mode signals; and transmit, to a host system and via an alert pin, a flag indicating that the memory device has entered the test mode.

In some implementations, a memory device includes one or more components configured to: detect, by a test mode monitor component of the memory device, that the memory device has entered a test mode based on one or more test mode signals; and store, to a mode register of the memory device, a value indicating that the memory device has entered the test mode.

In some implementations, a system includes a host system; a memory system; a host interface between the host system and the memory system; and one or more components configured to: detect, by the memory system, that the memory system has entered a test mode based on one or more test mode signals; and communicate, to the host system via a host interface, a message indicating that the memory system has entered the test mode.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
detect, by a test mode monitor component of the memory device, that the memory device has entered a test mode based on one or more test mode signals; and
provide, to a host system, a message indicating that the memory device has entered the test mode.

2. The memory device of claim 1, wherein the message comprises an alert flag, and wherein, to provide the message to the host system, the one or more components are further configured to:
transmit the alert flag to the host system via an alert pin.

3. The memory device of claim 1, wherein the one or more components are further configured to:
store a value indicating that the memory device has entered the test mode to a mode register of the memory device.

4. The memory device of claim 3, wherein the one or more components are further configured to:
obtain, from the host system, a read command for the mode register; and
transmit the value to the host system.

5. The memory device of claim 1, wherein the one or more components are further configured to:
obtain, from the host system, a guard key command sequence; and
initiate the test mode based on obtaining the guard key command sequence.

6. The memory device of claim 1, wherein the one or more components are further configured to:
determine an initiation condition associated with the test mode; and
provide, to the host system, a second message indicating the initiation condition.

7. The memory device of claim 1, wherein, to detect that the memory device has entered the test mode, the one or more components are configured to:
determine that a test mode signal of the one or more test mode signals has transitioned from a first logic state to a second logic state.

8. The memory device of claim 1, wherein the one or more test mode signals comprise a first test mode signal associated with a test mode command sequence and a second test mode signal associated with a guard key command sequence.

9. The memory device of claim 1, wherein the one or more test mode signals comprise one or more local test mode signals indicating whether respective components of the memory device have entered a test mode.

10. A memory device, comprising:
one or more components configured to:
detect, by a test mode monitor component of the memory device, that the memory device has entered a test mode based on one or more test mode signals; and
transmit, to a host system and via an alert pin, a flag indicating that the memory device has entered the test mode.

11. The memory device of claim 10, wherein the one or more components are further configured to:
obtain, from the host system, a guard key command sequence; and
initiate the test mode based on obtaining the guard key command sequence.

12. The memory device of claim 10, wherein the one or more components are further configured to:
determine an initiation condition associated with the test mode; and
provide, to the host system, a message indicating the initiation condition.

13. The memory device of claim 10, wherein, to detect that the memory device has entered the test mode, the one or more components are configured to:
determine that a test mode signal of the one or more test mode signals has transitioned from a first logic state to a second logic state.

14. The memory device of claim 10, wherein the one or more test mode signals comprise a first test mode signal associated with a test mode command sequence and a second test mode signal associated with a guard key command sequence.

15. A memory device, comprising:
one or more components configured to:
detect, by a test mode monitor component of the memory device, that the memory device has entered a test mode based on one or more test mode signals; and
store, to a mode register of the memory device, a value indicating that the memory device has entered the test mode.

16. The memory device of claim 15, wherein the one or more components are further configured to:
obtain, from a host system, a read command for the mode register; and
transmit the value to the host system.

17. The memory device of claim 15, wherein the one or more components are further configured to:
obtain, from a host system, a guard key command sequence; and
initiate the test mode based on obtaining the guard key command sequence.

18. The memory device of claim 15, wherein the one or more components are further configured to:
determine an initiation condition associated with the test mode; and
provide, to a host system, a message indicating the initiation condition.

19. The memory device of claim 15, wherein, to detect that the memory device has entered the test mode, the one or more components are configured to:
determine that a test mode signal of the one or more test mode signals has transitioned from a first logic state to a second logic state.

20. The memory device of claim 15, wherein the one or more test mode signals comprise a first test mode signal associated with a test mode command sequence and a second test mode signal associated with a guard key command sequence.

21. A system, comprising:
a host system;
a memory system;
a host interface between the host system and the memory system; and
one or more components configured to:
detect, by the memory system, that the memory system has entered a test mode based on one or more test mode signals; and
communicate, to the host system via the host system, a message indicating that the memory system has entered the test mode.

22. The system of claim 21, wherein the one or more components are further configured to:
initiate a safe mode of the memory system based on detecting that the memory system has entered the test mode.

23. The system of claim 21, wherein the message comprises an alert flag, and wherein, to provide the message to the host system, the one or more components are further configured to:
transmit the alert flag to the host system via an alert pin.

24. The system of claim 21, wherein the one or more components are further configured to:
store, to a mode register of the memory system, a value indicating that the memory system has entered the test mode.

25. The system of claim 24, wherein the one or more components are further configured to:
communicate, to the memory system and via the host interface, a read command for the mode register; and
communicate, to the host system and via the host interface, the value.
